(19) United States
(12) Patent Application Publication
(10) Pub. No.: US 2009/0191706 A1
(43) Pub. Date: Jul. 30, 2009

(54) METHOD FOR FABRICATING A SEMICONDUCTOR DEVICE

(76) Inventor: Takeo Kubota, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/343,265

(22) Filed: Dec. 23, 2008

(30) Foreign Application Priority Data
Dec. 28, 2007 (JP) 2007-339321

(51) Int. Cl. H01L 21/768; H01L 21/3213

(52) U.S. Cl. 438/653; 438/669; 257/E21.305; 257/E21.584

(57) ABSTRACT

A method for fabricating a semiconductor device, including forming a dielectric film above a substrate; forming a metal containing film above the dielectric film; forming at least one carbon containing film of a silicon carbon containing film containing silicon and carbon and a nitrogen carbon containing film containing nitrogen and carbon above the metal containing film; etching the carbon containing film selectively; etching the metal containing film selectively to transfer an opening of the carbon containing film formed by etching; and etching the dielectric film using the carbon containing film and the metal containing film as masks in a state in which a surface of the carbon containing film other than the opening is exposed.

### CROSS-REFERENCE TO RELATED APPLICATION

This application is based upon and claims the benefit of priority from prior Japanese Patent Application No. 2007-339321 filed on Dec. 28, 2007 in Japan, the entire contents of which are incorporated herein by reference.

### BACKGROUND OF THE INVENTION

1. Field of the Invention

The present invention relates to a method for fabricating a semiconductor device and, for example, relates to a fabricating method for forming a damascene wire.

2. Related Art

In recent years, with ever higher integration and higher performance of semiconductor integrated circuits (LSI), new microprocessing technologies have been developed. In particular, to achieve an ever faster speed of LSI, there has been a growing trend recently to replace the conventional wire material of aluminum (Al) alloys with copper (Cu) or Cu alloys (hereinafter, called Cu together) having lower resistance. Since it is difficult to apply the dry etching method, which is frequently used for forming an Al alloy wire, to Cu for microprocessing, the so-called damascene process is mainly adopted for Cu, in which a Cu film is deposited on a dielectric film to which groove processing has been provided and then the Cu film is removed except in portions where the Cu film is embedded inside a groove by chemical-mechanical polishing (CMP) to form an embedded wire. The Cu film is generally formed as a laminated film to a thickness of about several hundred nm by the electro-plating method after a thin seed layer being formed by the sputter process. Further, when a multilayer Cu wire is formed, particularly a wire formation method called a dual damascene structure can be used. Using this method, a dielectric film is deposited on a lower layer wire and predetermined via holes and a trench (wiring groove) for an upper layer wire are formed and then, Cu to be a wire material is embedded in the via holes and trench simultaneously and further, unnecessary Cu in the upper layer is removed by the CMP for planarization to form an embedded wire.

Then recently, the use of a low dielectric constant material film (low-k film) having a low relative dielectric constant is examined as an inter-level dielectric. That is, an attempt is made to reduce parasitic capacitance between wires by using a low dielectric constant material film (low-k film) whose relative dielectric constant k is 3 or less, instead of a silicon oxide film (SiO₂) whose relative dielectric constant k is about 4.2. To prevent diffusion of Cu into the low-k film, for example, a barrier metal film of titanium nitride (TiN) or the like is first formed on the wall surface and at the bottom of a groove and then Cu is embedded.

Here, since a resist material has low resistance to etching, it is necessary to make a resist film thicker to etch a low-k film using a resist pattern. Making the resist film thicker lowers resolving power, leading to lower dimensional accuracy. Further, if a resist pattern is used for etching a low-k film, there are problems of degradation in insulation of the low-k film because carbon (C) escapes from the low-k film due to working damage from dry etching, ashing, cleaning and the like and an occurrence of voids. If the relative dielectric constant k rises due to degradation in insulation or voids arise in an inter-level dielectric, insulation properties between wires deteriorate so that sufficient electric characteristics cannot be obtained. Thus, the establishment of a process to reduce an influence of working damage is a new challenge. From that viewpoint, a technique to etch a low-k film by a hard mask by forming a hard mask material on the low-k film and etching the hard mask material formed thinly using a resist pattern is examined. Accordingly, the resist film can be made thinner. As a result, dimensional accuracy of a resist pattern can be improved. Further, ashing after etching a low-k film becomes unnecessary and thus, exposure to plasma during ashing is eliminated so that an effect of controlling degradation in insulation correspondingly can be expected. However, if a hard mask is formed from a dielectric film material, a problem of lower dimensional accuracy of the etched low-k film arises because dimensions of the hard mask are deformed and gradually shaved during etching due to a small selection ratio to a low-k film. Thus, maintaining dimensional accuracy by adopting a metal material having a large selection ratio to a low-k film as a hard mask is examined (For example, see “‘O. Hinsinger et al.’, IEDM Technical Digest, p. 321, 2004”, “‘R. Fox et al.’, IEDM Technical Digest, Session 4. 2, 2005.”, or “‘V. Arnal et al.’, 2006 IEEE International Interconnect Technology Conference, p. 213”).

However, when a low-k film was etched using a metal material as a hard mask, a problem that dielectric breakdown strength of the low-k film deteriorates due to working damage arose. Thus, sufficient electric characteristics cannot be obtained by simply using a metal material as a hard mask and thus, further improvement is demanded.

### BRIEF SUMMARY OF THE INVENTION

In accordance with one aspect of the present invention, a method for fabricating a semiconductor device is provided, which includes forming a dielectric film above a substrate; forming a metal containing film above the dielectric film; forming at least one carbon containing film of a silicon carbon containing film containing silicon and carbon and a nitrogen carbon containing film containing nitrogen and carbon above the metal containing film; etching the carbon containing film selectively; etching the metal containing film selectively to transfer an opening of the carbon containing film formed by etching; and etching the dielectric film using the carbon containing film and the metal containing film as masks in a state in which a surface of the carbon containing film other than the opening is exposed.

In accordance with another aspect of this invention, a method for fabricating a semiconductor device includes forming a dielectric film above a substrate; forming a metal containing film above the dielectric film; forming a carbon containing film whose resistance to etching is stronger than that of the dielectric film above the metal containing film; etching the carbon containing film selectively; etching the metal containing film selectively to transfer an opening of the carbon containing film formed by etching; and etching the dielectric film using the carbon containing film and the metal containing film as masks in a state in which a surface of the carbon containing film other than the opening is exposed.

### BRIEF DESCRIPTION OF THE DRAWINGS

FIG. 1 is a flow chart showing features of a method for fabricating a semiconductor device according to an embodiment 1.

FIG. 2A to FIG. 2D are process sectional views showing processes performed corresponding to the flow chart in FIG. 1.

FIG. 3A to FIG. 3C are process sectional views showing processes performed corresponding to the flow chart in FIG. 1.

FIG. 4A to FIG. 4C are process sectional views showing processes performed corresponding to the flow chart in FIG. 1.

FIG. 5A to FIG. 5C are process sectional views showing processes performed corresponding to the flow chart in FIG. 1.

FIG. 6A to FIG. 6C are process sectional views showing processes performed corresponding to the flow chart in FIG. 1.

FIG. 7A and FIG. 7B are process sectional views showing processes performed corresponding to the flow chart in FIG. 1.

FIG. 8A and FIG. 8B are views exemplifying a difference of results depending on presence/absence of a C containing film when a dielectric film is etched using a metal mask.

FIG. 9A and FIG. 9B are views exemplifying a difference of results of dielectric film etching using a hard mask in the embodiment 1 and a dielectric film hard mask.

FIG. 10A and FIG. 10B are views exemplifying a difference of results of dielectric film etching when the position of the C containing film and that of a metal containing film are reversed.

FIG. 11 is a flow chart showing features of the method for fabricating a semiconductor device according to an embodiment 2.

FIG. 12 is a process sectional view showing a process performed in a metal containing film etching process (S122) in FIG. 11.

FIG. 13 is a flow chart showing features of the method for fabricating a semiconductor device according to an embodiment 3.

FIG. 14A to FIG. 14C are process sectional views showing processes performed corresponding to the flow chart in FIG. 13.

FIG. 15A to FIG. 15C are process sectional views showing processes performed corresponding to the flow chart in FIG. 13.

FIG. 16 is a flow chart showing features of the method for fabricating a semiconductor device according to an embodiment 4.

FIG. 17 is a process sectional view showing a process performed in the metal containing film etching process (S122) in FIG. 16.

### DETAILED DESCRIPTION OF THE INVENTION

In embodiments shown below, methods for fabricating a semiconductor device that control working damage of a dielectric film when the dielectric film is etched using a metal material as a hard mask will be described.

### Embodiment 1

In the embodiment 1, an example in which etching is performed up to a carbon containing film using a resist pattern will be described. The embodiment 1 will be described below using drawings.

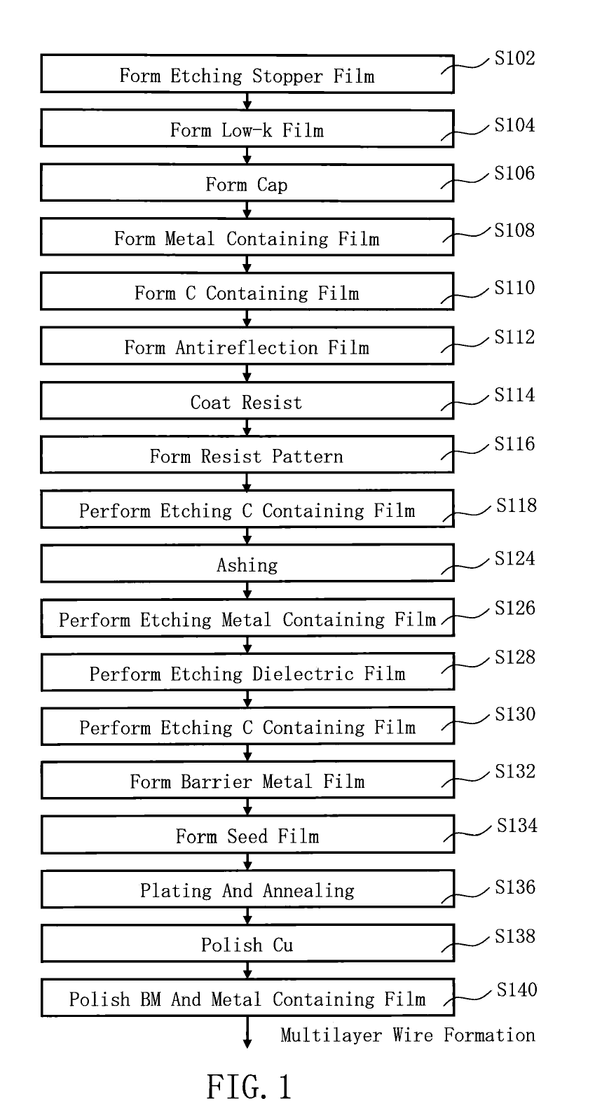

FIG. 1 is a flow chart showing features of the method for fabricating a semiconductor device according to the embodiment 1. In FIG. 1, the method for fabricating a semiconductor device according to the embodiment 1 performs a series of processes including an etching stopper film formation process (S102), low-k film formation process (S104), cap film formation process (S106), metal containing film formation process (S108), carbon (C) containing film formation process (S110), antireflection film formation process (S112), resist coating process (S114), resist pattern formation process (S116), C containing film etching process (S118), ashing process (S124), metal containing film etching process (S126), dielectric film etching process (S128), C containing film etching process (S13O), barrier metal (BM) film formation process (S132), seed film formation process (S134), plating and annealing process (S136), copper (Cu) polishing process (S138), and BM and metal containing film polishing process (S140).

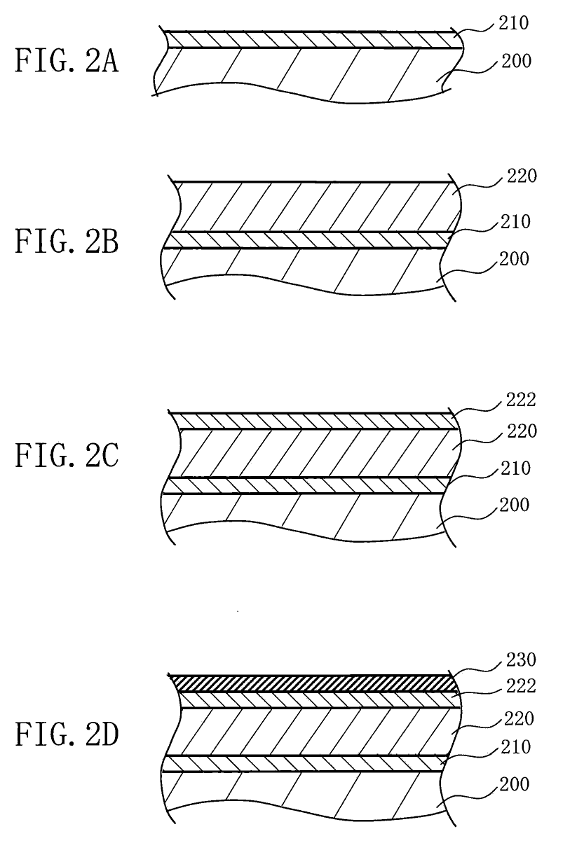

FIG. 2A to FIG. 2D are process sectional views showing processes performed corresponding to the flow chart in FIG. 1. FIG. 2A to FIG. 2D show the etching stopper film formation process (S102) to the metal containing film formation process (S108) in FIG. 1.

In FIG. 2A, as the etching stopper film formation process (S102), an etching stopper film 210 is formed on a substrate 200 by the chemical vapor deposition (CVD) method to a thickness of, for example, 25 nm. For example, silicon carbonitride (SiCN), silicon carbide (SiC), or silicon nitride (SiN) is a suitable material for the etching stopper film. Or, a laminated film of a non-porous SiCO film (dense SiCO film) of the thickness of, for example, 20 nm and an SiCN film of the thickness of, for example, 5 nm is also suitable as an etching stopper film. The formation method is not limited to the CVD method and a different method may also be used to form an etching stopper film. A silicon wafer of 300 mm in diameter, for example, is used as the substrate 200. Here, an illustration of a device portion is omitted. Moreover, various semiconductor elements (not shown) such as metal wires and contact plugs or layers having a structure may be formed on the substrate 200. Or, other layers may be formed.

In FIG. 2B, as the low-k film formation process (S104), a low-k film 220 using a porous low dielectric constant material is formed on the etching stopper film 210 to a thickness of, for example, 100 nm. By forming the low-k film 220, an inter-level dielectric whose relative dielectric constant k is less than 3.5 can be obtained. Here, as an example, a porous SiOC film is formed from a low dielectric constant material whose relative dielectric constant k is less than 2.5 by using the CVD method. The formation method is not limited to the CVD method and, for example, the SOD (spin on dielectric coating) method by which a thin film is formed by spin-coating a solution and providing heat treatment may also be suitably used. Porous methyl silsesquioxane (MSQ), for example, can be used as a material of the low-k film 220 formed by the SOD method. In addition to MSQ, for example, the low-k film 220 may be formed by using at least one film selected from a group including a film having siloxane backbone structures such as polymethyl siloxane, polysiloxane, and hydrogen silsesquioxane, that having organic resin as a main component such as polyarylene ether, polybenzo oxazole, and polybenzo cyclobutene, and a porous film such as a porous silica film. Using such materials of the low-k film 220, a low dielectric constant whose relative dielectric constant is less than 2.5 can be obtained. When the SOD method is used, for example, a film is formed by a spinner and the formed wafer is baked in a nitrogen atmosphere on a hot plate and then, finally the wafer is cured at a temperature higher than the baking temperature in the nitrogen atmosphere on the hot plate to form the low-k film 220. By suitably adjusting the low-k material and formation conditions, a porous dielectric film having predetermined property values can be obtained.

In FIG. 2C, as the cap film formation process (S106), a cap film 222 is formed on the low-k film 220 by using the CVD method to a thickness of, for example, 60 nm. Silicon oxide (SiO₂) or non-porous SiOC is suitable as the material of the cap film 222.

Here, 100 nm of the low-k film 220 and 60 nm of the cap film 222 to be main components are formed as inter-level dielectrics, but inter-level dielectrics are not limited to these. For example, more microscopically, 60 nm of the low-k film 220 of MSQ and 20 nm of the cap film 222 of non-porous SiOC are also suitable as inter-level dielectrics.

In FIG. 2D, as the metal containing film formation process (S108), a metal containing film 230 using a metal containing material is formed on the cap film 222. A thin film of a tantalum nitride (TaN) film is deposited in a sputtering apparatus using the sputter process, which is one of the physical vapor deposition (PVD) method, to a thickness of, for example, 30 nm to form the metal containing film 230. The deposition method of the metal containing film 230 is not limited to the PVD method and the atomic layer deposition (ALD) method (or the atomic layer chemical vapor deposition (ALCVD) method) or the CVD method can also be used. The coverage factor can be made better than when the PVD method is used. In addition to TaN, metal such as tantalum (Ta), titanium (Ti), ruthenium (Ru), tungsten (W), zirconium (Zr), aluminum (Al), and niobium (Nb), nitride of these metals including titanium nitride (TiN) and tungsten nitride (WN), other materials containing these metals, and a combination of these materials can be used as the material of the metal containing film 230. Particularly, the same material as that of a barrier metal film described later is preferably used as the material of the metal containing film 230.

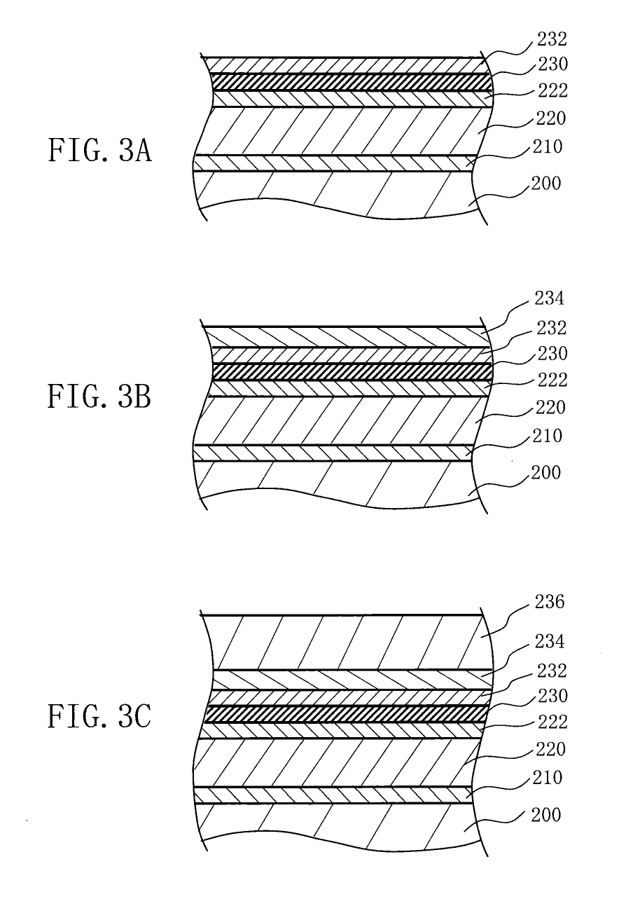

FIG. 3A to FIG. 3C are process sectional views showing processes performed corresponding to the flow chart in FIG. 1. FIG. 3A to FIG. 3C show the C containing film formation process (S110) to the resist coating process (S114) in FIG. 1.

In FIG. 3A, as the C containing film formation process (S110), a C containing film 232 using at least one of C containing materials of a silicon carbon containing film containing silicon (Si) and carbon (C) and a nitrogen carbon containing film containing nitrogen (N) and carbon (C) are formed. For example, a silicon carbide (SiC) film is formed on the metal containing film 230 using the CVD method to a thickness of, for example, 30 nm. In addition to SiC, as an example of material of a film containing silicon and carbon, dense SiCO or SiCN is suitable as the material of the C containing film 232. Carbon nitride (CN) is suitable, as an example of material of a film containing nitrogen and carbon. That is, C containing materials that are different from a resist material and whose resistance to etching is stronger than that of the cap film 222 or the low-k film 220 can be used as the material of the metal containing film 230. With Si or N being contained in the C containing film 232, in addition to C, resistance to etching can be made stronger than that of the cap film 222 or the low-k film 220.

In FIG. 3B, as the antireflection film formation process (S112), an antireflection film 234 is formed on the C containing film 232.

In FIG. 3C, as the resist coating process (S114), the antireflection film 234 is coated with a resist material to form a resist film 236. In the present embodiment, the resist film 236 can be made thinner compared when an inter-level dielectric is etched using a resist pattern as a mask because the inter-level dielectric such as the cap film 222 and the low-k film 220 is etched using, as described later, the C containing film 232 and the metal containing film 230 as hard masks.

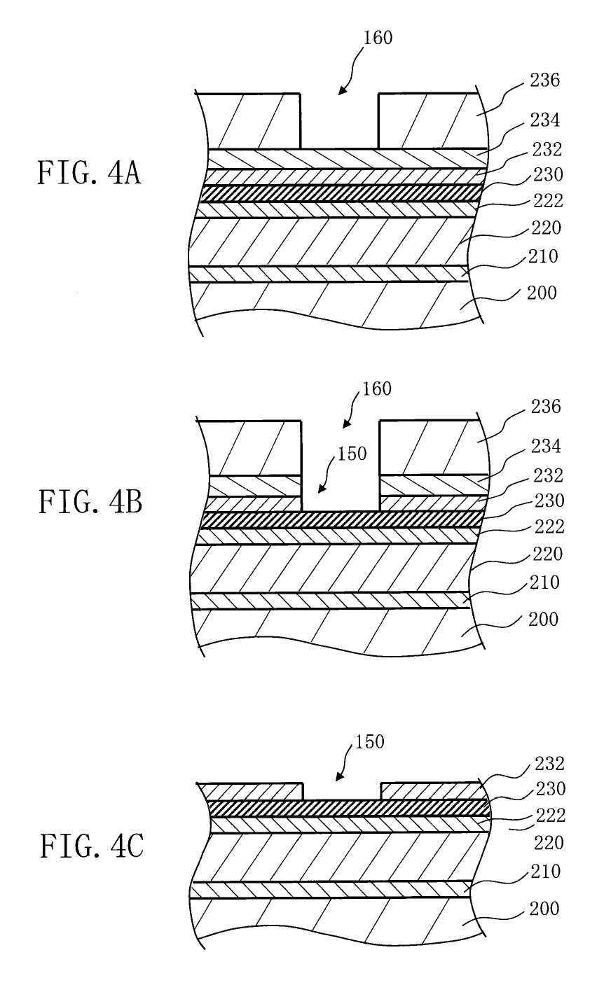

FIG. 4A to FIG. 4C are process sectional views showing processes performed corresponding to the flow chart in FIG. 1. FIG. 4A to FIG. 4C show the resist pattern formation process (S116) to the ashing process (S124) in FIG. 1.

In FIG. 4A, as the resist pattern formation process (S116), an opening 160 is selectively formed by forming a resist pattern on the antireflection film 234 by undergoing a lithography process such as exposure process. Since the resist film 236 can be made thinner compared when an inter-level dielectric is etched using a resist pattern as a mask, dimensional accuracy of the opening 160 can be improved correspondingly. Thus, resolution in pattern formation can be improved.

In FIG. 4B, as the C containing film etching process (S118), an opening 150 is formed by selectively etching the exposed antireflection film 234 and the C containing film 232 thereunder by the anisotropic etching method using the resist pattern as a mask. Here, the metal containing film 230 can be used as an etching stopper. A fluorine gas, for example, a C₄F₈ gas can suitably be used as an etching gas. By using the anisotropic etching method for removal, the opening 150 can be formed substantially perpendicularly to the surface of the substrate 200. As an example, for example, the opening 150 may be formed by the reactive ion etching method.

In FIG. 4C, as the ashing process (S124), the resist film 236 remaining on the C containing film 232 is removed by ashing. At this point, the antireflection film 234 can also be removed together. For example, ashing is performed in a different reaction vessel from that used in the C containing film etching process (S118). The C containing film 232 positioned below the antireflection film 234 uses, as described above, a material with Si or N added, in addition to C, such as SiC, dense SiCO, SiCN, and CN that is not ashed by the ashing process. Thus, the C containing film 232 that causes C containing reaction products which protect the low-k film 220 as described below to be generated can be arranged at the top surface of the substrate. By removing a resist pattern and the antireflection film 234 before the low-k film 220 being etched, the total thickness of film acting as a mask material when the low-k film 220 is etched can be made thinner so that dimensional accuracy when the low-k film 220 is etched can be improved.

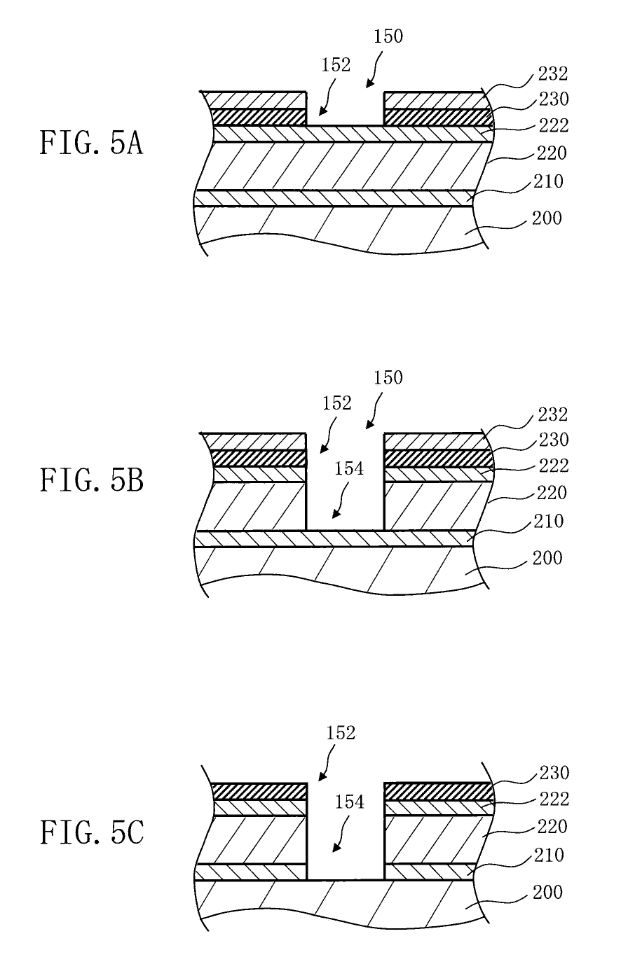

FIG. 5A to FIG. 5C are process sectional views showing processes performed corresponding to the flow chart in FIG. 1. FIG. 5A to FIG. 5C show the metal containing film etching process (S126) to the C containing film etching process (S130) in FIG. 1.

In FIG. 5A, as the metal containing film etching process (S126), an opening 152 is formed by selectively etching the exposed metal containing film 230 by the anisotropic etching method using the C containing film 232 as a hard mask. For example, etching is performed in a different reaction vessel from that used in the C containing film etching process (S118) or the ashing process (S124). Here, the cap film 222 can be used as an etching stopper. A chlorine gas, for example, a Cl₂ gas can suitably be used as an etching gas. Also here, by using the anisotropic etching method for removal, as described above, the opening 152 can be formed substantially perpendicularly to the surface of the substrate 200. As an example, for example, the opening 152 may be formed by the reactive ion etching method.

In FIG. 5B, as the dielectric film etching process (S128), an opening 154 is formed by selectively etching the exposed cap film 222 and the low-k film 220 thereunder by the anisotropic etching method using the C containing film 232 and the metal containing film 230 as hard masks in a state in which a surface of the C containing film 232 different from the opening 150 is exposed. Here, since the antireflection film 234 has been removed, the C containing film 232 of various films formed on the substrate 200 is positioned at the top surface. With the C containing film 232 to which Si or N is added positioned at the top surface, C containing reaction products are generated from the C containing film 232 when the cap film 222 and the low-k film 220 are etched so that fluctuations in dimension caused by bowing can be inhibited. For example, the substrate 200 is brought back to the reaction vessel used in the C containing film etching process (S118) for etching. Here, the etching stopper film 210 can be used as an etching stopper. A fluorine gas, for example, a C₄F₈ gas can suitably be used as an etching gas. Also here, by using the anisotropic etching method for removal, as described above, the opening 154 can be formed substantially perpendicularly to the surface of the substrate 200. As an example, for example, the opening 154 may be formed by the reactive ion etching method.

In FIG. 5C, as the C containing film etching process (S130), the C containing film 232 remaining on the metal containing film 230 is removed by etching. At this point, the etching stopper film 210 can also be etched together to remove the etching stopper film 210 together with the C containing film 232. The etching stopper film 210 uses, as described above, SiCN, SiC, SiN, or dense SiCO as the material thereof and the C containing film 232 uses, as described above, SiC, dense SiCO, SiCN, or CN as the material thereof. Since, as described above, the etching stopper film 210 uses the same material as the C containing film 232 or a material whose etching selection ratio to the C containing film 232 is small, the etching stopper film 210 is etched together when the C containing film 232 is etched so that the etching stopper film 210 can be removed together with the C containing film 232.

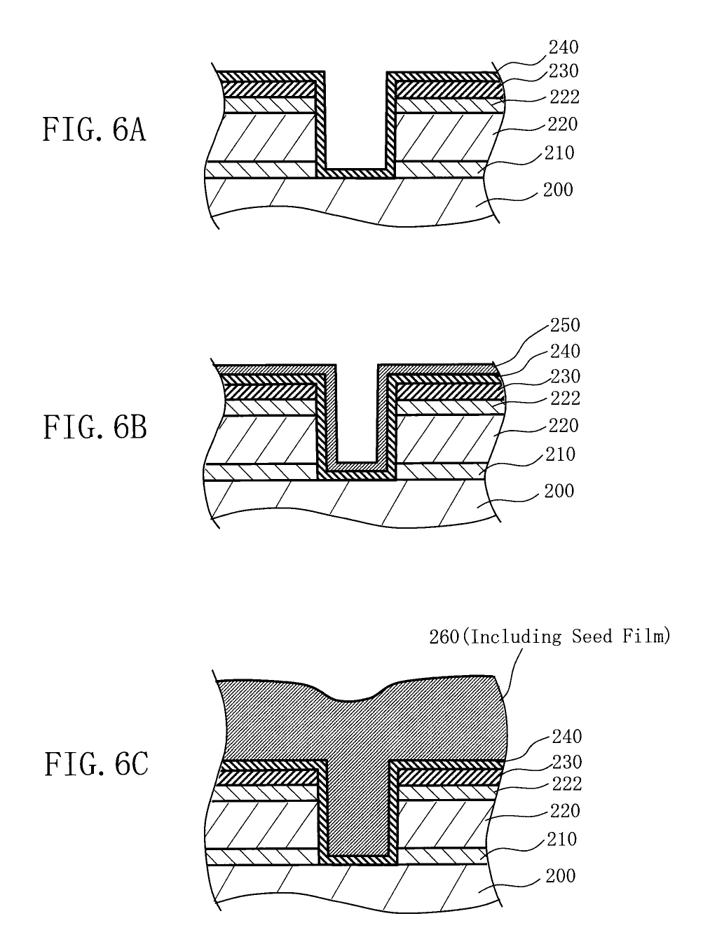

FIG. 6A to FIG. 6C are process sectional views showing processes performed corresponding to the flow chart in FIG. 1. FIG. 6A to FIG. 6C show the BM film formation process (S132) to the plating and annealing process (S136) in FIG. 1.

In FIG. 6A, as the BM film formation process (S132), a barrier metal film 240 using a barrier metal material to be an example of conductive material is formed on the inner surface of the openings 152 and 154 formed by etching and on the surface of the metal containing film 230. A TaN film is deposited in a sputtering apparatus using the sputter process to a thickness of, for example, 5 nm to form the barrier metal film 240. The deposition method of the barrier metal material is not limited to the PVD method and the atomic layer deposition (ALD) method or the CVD method can also be used. The coverage factor can be made better than when the PVD method is used. In addition to TaN, Ta, Ti, W, TiN, WN, or a laminated film of a combination of these such as Ta and TaN can be used as the material of the barrier metal film. Or, like the metal containing film 230, a metal such as Ru, Zr, Al, and Nb, or nitride of these metals can also be used. Here, the barrier metal film 240 using the same material as the metal containing film 230 is formed on the metal containing film 230 and on the inner surface of the opening 154 of the low-k film 220 etc. in a state in which only the metal containing film 230 of the C containing film 232 and the metal containing film 230 used as masks when the low-k film 220 was etched is left.

In FIG. 6B, as the seed film formation process (S134), a Cu thin film to be a cathode electrode in the next process, the electro-plating process, is deposited (formed) as a seed film 250 on the inner wall of the openings 152 and 154 where the barrier metal film 240 is formed and on the surface of the substrate 200 by the PVD method such as the sputter process.

In FIG. 6C, as the plating and annealing process (S136), a Cu film 260 to be an example of conductive material is deposited on the surface of the openings 152 and 154 and the substrate 200 where the seed film 250 is formed with the seed film 250 as the cathode electrode by the electrochemical growth method such as electro-plating. Here, for example, the Cu film 260 is deposited to a thickness of 200 nm and then, after the deposition, annealing is performed, for example, at 250° C. for 30 min.

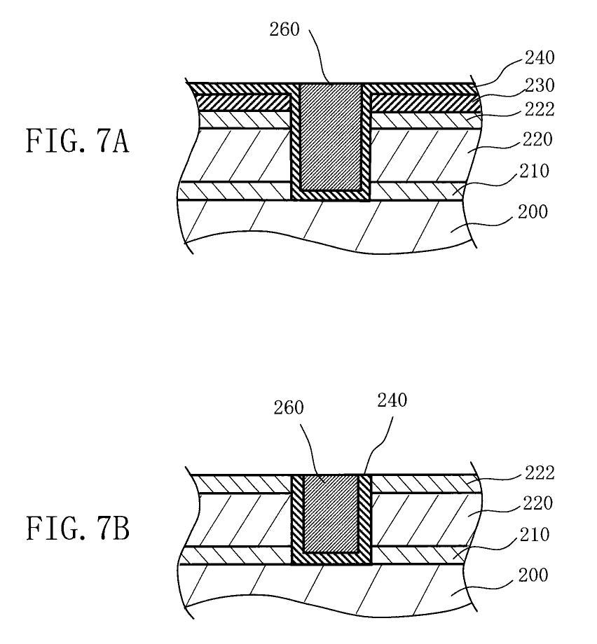

FIG. 7A and FIG. 7B are process sectional views showing processes performed corresponding to the flow chart in FIG. 1. FIG. 7A and FIG. 7B show the Cu polishing process (S138) and the BM and metal containing film polishing process (S140) in FIG. 1.

In FIG. 7A, as the Cu polishing process (S138), the surface of the substrate 200 is polished by the CMP method to remove the Cu film 260 including the seed film 250 to be a wire layer deposited on the surface excluding the opening by polishing. By polishing the conductive material in this manner, the conductive material is selectively left in the openings 152 and 154 where the barrier metal film 240 is formed on the inner surface thereof.

In FIG. 7B, as the BM and metal containing film polishing process (S140), after the conductive material being selectively left in the openings 152 and 154, as described above, the surface of the substrate 200 is polished by the CMP method to remove the barrier metal film 240 and the metal containing film 230 deposited on the surface excluding the opening by polishing. Since the barrier metal film 240 and the metal containing film 230 are formed from the same material, the barrier metal film 240 and the metal containing film 230 can be polished together. As a result, the substrate 200 can be planarized, as shown in FIG. 7B. With the above processes, a Cu wire can be formed. Here, for example, the cap film 222 having the thickness of 60 nm is polished up to the thickness of 30 nm. However, the cap film 222 is not limited to polishing and the cap film 222 may be formed to a thickness when completed in advance so that the cap film 222 need not be polished in the polishing process.

Here, the Cu film 260 deposited in the opening 152 is also polished when the barrier metal film 240 is polished and thus, the polishing liquid used for polishing such as slurry and the cleaning liquid used for cleaning after polishing are adjusted so that corrosion caused by a potential difference generated between dissimilar metals of the barrier metal material and Cu is not caused. On the other hand, if the metal containing film 230 is formed from a different material from the barrier metal material, there arises a need to adjust the polishing liquid and cleaning liquid among three dissimilar materials to prevent corrosion. Adjustments among three dissimilar materials are very difficult. Thus, in the present embodiment, the barrier metal film 240 and the metal containing film 230 are formed from the same material, reducing adjustments between two dissimilar materials that are easier to achieve.

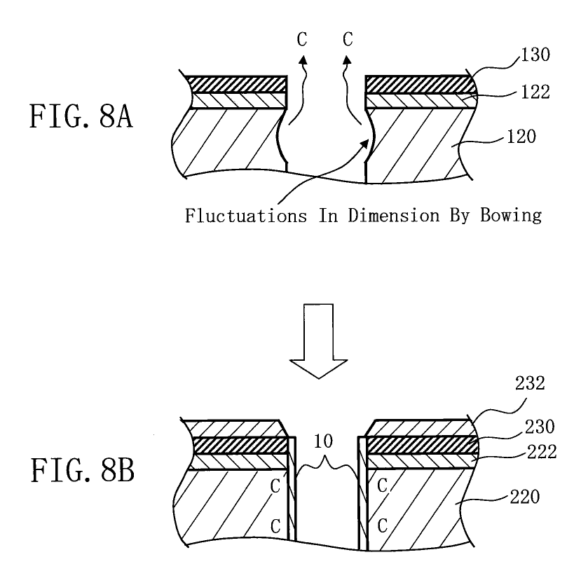

FIG. 8A and FIG. 8B are views exemplifying a difference of results depending on presence/absence of a C containing film when a dielectric film is etched using a metal mask.

As a comparative example, a cap film 122 and a low-k film 120 are etched using a metal containing film 130 as a hard mask when a C containing film is not present on the surface. In this case, as shown in FIG. 8A, working damage occurs in the low-k film 120 due to an influence of plasma exposure during etching or the like. Thus, carbon (C) escapes from the inner wall of the opening of the low-k film 120 and the surface thereof degenerates. As a result, fluctuations in dimension caused by bowing occur and the width of the low-k film 120 becomes narrower at some locations. Therefore, a problem like insulation properties being degraded is caused.

In the present embodiment, by contrast, the cap film 222 and the low-k film 220 are etched using the C containing film 232 and the metal containing film 230 used as hard masks when the C containing film 232 is exposed. In this case, as shown in FIG. 8B, fluctuations in dimension caused by bowing can be inhibited. This can be considered as follows: C containing reaction products 10 are generated from the C containing film 232 during etching and the C containing reaction products 10 inhibit C from escaping from the inner wall of the opening of the low-k film 220 by being stuck to the inner wall of the opening of the cap film 222 and the low-k film 220. On the other hand, in the comparative example in FIG. 8A, the C containing reaction products 10 are not generated and thus, the above result is considered to be generated. In the present embodiment, as described above, degradation in insulation of inter-level dielectrics can be avoided or reduced by forming the exposed C containing film 232 on the metal containing film 230. In other words, fluctuations in dimension caused by bowing can be inhibited by performing dry etching while reaction products containing C being deposited on a processed surface of an inter-level dielectric formed by dry etching. As a result, degradation in insulation of inter-level dielectrics can be avoided or reduced.

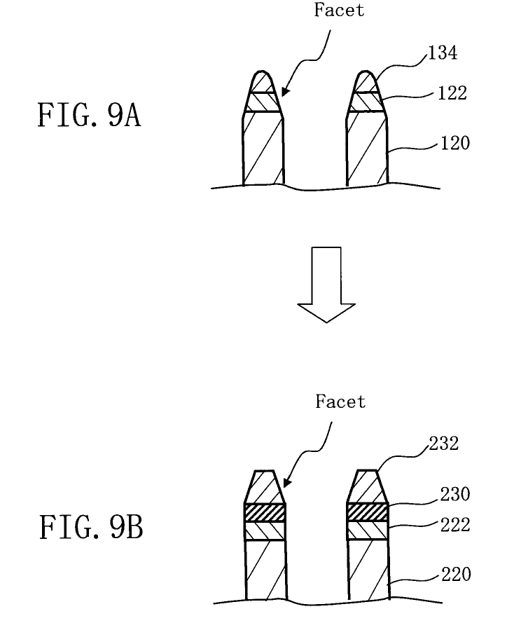

FIG. 9A and FIG. 9B are views exemplifying a difference of results of dielectric film etching using a hard mask in the embodiment 1 and a dielectric film hard mask.

As a comparative example, the cap film 122 and the low-k film 120 thereunder to be dielectric films are etched using a silicon (Si) based dielectric film 134, instead of a metal mask as a hard mask. In this case, as shown in FIG. 9A, a facet in which the width and film thickness gradually become thinner from a pattern edge occur even in the cap film 122 or the low-k film 120, making it difficult to maintain dimensions. This phenomenon becomes conspicuous particularly when an opening such as a trench is formed with a narrow space width. In the present embodiment, on the other hand, the cap film 222 and the low-k film 220 are etched using the C containing film 232 and the metal containing film 230 as hard masks. In this case, as shown in FIG. 9B, while a facet occurs in the C containing film 232, no facet occurs in the metal containing film 230 having a large etching selection ratio to the low-k film 220 or the like or can be made negligible. Thus, dimensional accuracy can be maintained even when an opening such as a trench is formed particularly with a narrow space width.

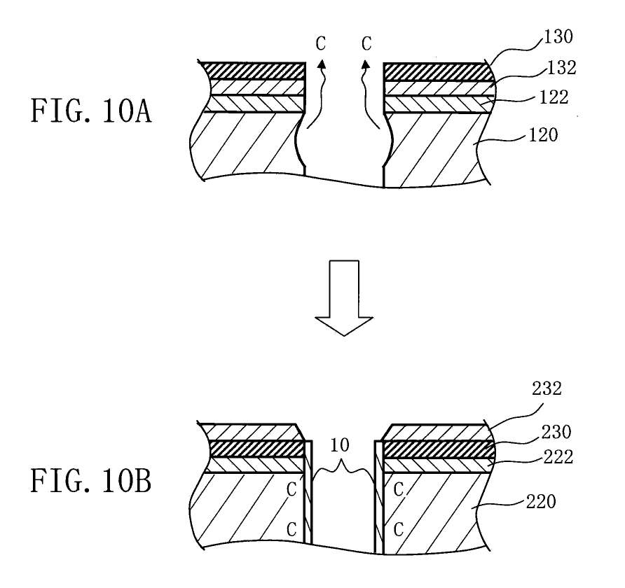

FIG. 10A and FIG. 10B are views exemplifying a difference of results of dielectric film etching when the position of a C containing film and that of a metal containing film are reversed. As a comparative example, the metal containing film 130 is formed on a C containing film 132 and while the metal containing film 130 is exposed, the cap film 122 and the low-k film 120 are etched using the C containing film 132 and the metal containing film 130 as hard masks. In this case, as shown in FIG. 10A, the width of the low-k film 120 becomes narrower at some locations because dimensions fluctuate is caused by bowing. In the present embodiment, on the other hand, the C containing film 232 is formed on the metal containing film 230 and while the C containing film 232 is exposed, the cap film 222 and the low-k film 220 are etched using the C containing film 232 and the metal containing film 230 as hard masks. In this case, as shown in FIG. 10B, fluctuations in dimension caused by bowing can be inhibited. It is clear also from this comparative example that etching while the C containing film 232 is exposed is appropriate to cause the C containing reaction products 10 to be generated from the C containing film 232.

### Embodiment 2

The embodiment 1 is described by taking the opening 150 formed in the C containing film 232 using a resist pattern as a mask and the opening 152 formed in the metal containing film 230 using the C containing film 232 as a hard mask as an example. In the embodiment 2, an example in which the opening 150 is formed in the C containing film 232 and further the opening 152 is formed in the metal containing film 230 using a resist pattern as a mask will be described. The embodiment 2 will be described below using drawings.

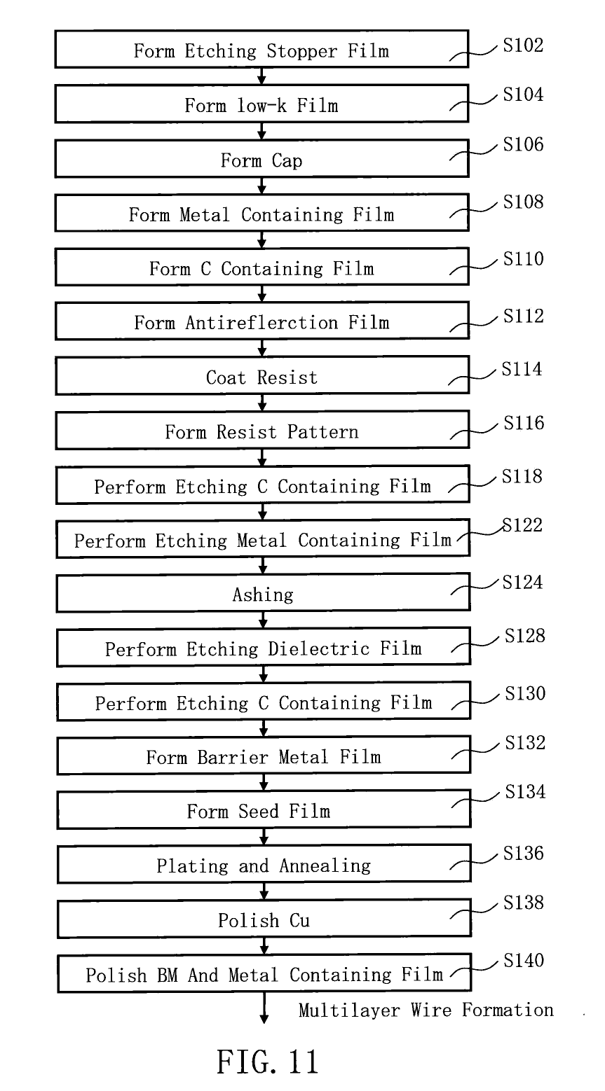

FIG. 11 is a flow chart showing features of the method for fabricating a semiconductor device according to the embodiment 2. FIG. 11 is the same as FIG. 1 except that the metal containing film etching process (S122) is added between the C containing film etching process (S118) and the ashing process (S124) and the metal containing film etching process (S126) is deleted. Thus, the etching stopper film formation process (S102) to the C containing film etching process (S118) are the same as in the embodiment 1.

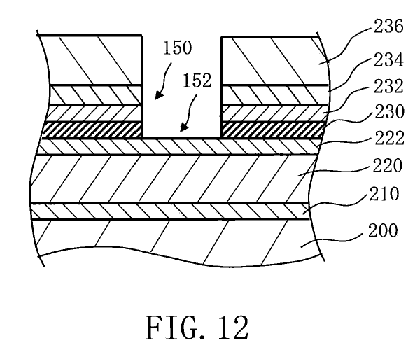

FIG. 12 is a process sectional view showing a process performed in the metal containing film etching process (S122) in FIG. 11. In FIG. 12, as the metal containing film etching process (S122), the opening 152 is formed by selectively etching the exposed metal containing film 230 by the anisotropic etching method using a resist pattern by the resist film 236 as a mask from the state shown in FIG. 4B. For example, etching is performed in a different reaction vessel from that in the C containing film etching process (S118) or the ashing process (S124). Here, the cap film 222 can be used as an etching stopper. A chlorine gas, for example, a Cl₂ gas can suitably be used as an etching gas. Also here, by using the anisotropic etching method for removal, as described above, the opening 152 can be formed substantially perpendicularly to the surface of the substrate 200. As an example, for example, the opening 152 may be formed by the reactive ion etching method.

Then, the state in FIG. 5A is created after performing the ashing process (S124). At this point, the cap film 222 positioned below the opening 152 protects the low-k film 220 from plasma during ashing. Hereafter, processes are the same as in the embodiment 1.

In the embodiment 2, the C containing film 232 can be prevented from producing a facet when the metal containing film 230 is etched by using a resist pattern formed on the C containing film 232 as a mask, instead of using the C containing film 232 as a hard mask while the C containing film 232 is exposed. As a result, a hard mask pattern of the C containing film 232 can be maintained in a satisfactory state until the low-k film 220 is etched. Also as a result, the opening 154 for embedding a Cu wire can be formed with more precise dimensions than those in the embodiment 1.

### Embodiment 3

In the embodiment 1 described above, the antireflection film 234 is formed after the C containing film 232 being formed. In the embodiment 3, a configuration in which an antireflection film serving also as a C containing film is used without using the C containing film 232 alone will be described. The embodiment 3 will be described below using drawings.

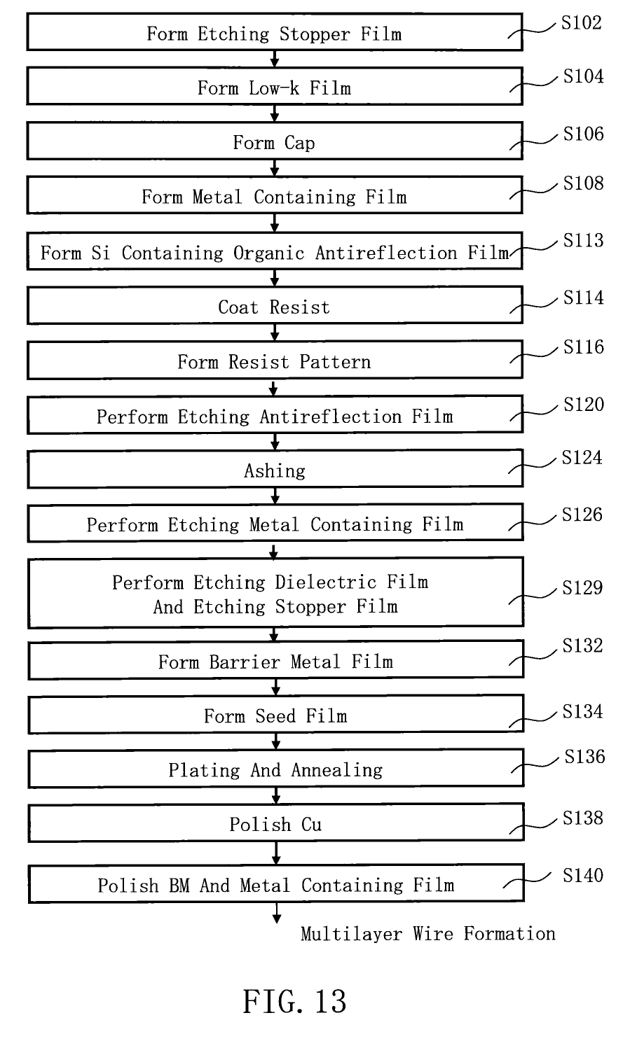

FIG. 13 is a flow chart showing features of the method for fabricating a semiconductor device according to the embodiment 3. FIG. 13 is the same as FIG. 1 except that the C containing film formation process (S110) and the C containing film etching process (S130) are removed, the antireflection film formation process (S112) is replaced by an Si containing organic anti reflection film formation process (S113), the C containing film etching process (S118) is replaced by an antireflection film etching process (S120), and the dielectric film etching process (S128) is replaced by a dielectric film and etching stopper film etching process (S129). Thus, the etching stopper film formation process (S102) to the metal containing film formation process (S108) are the same as in the embodiment 1.

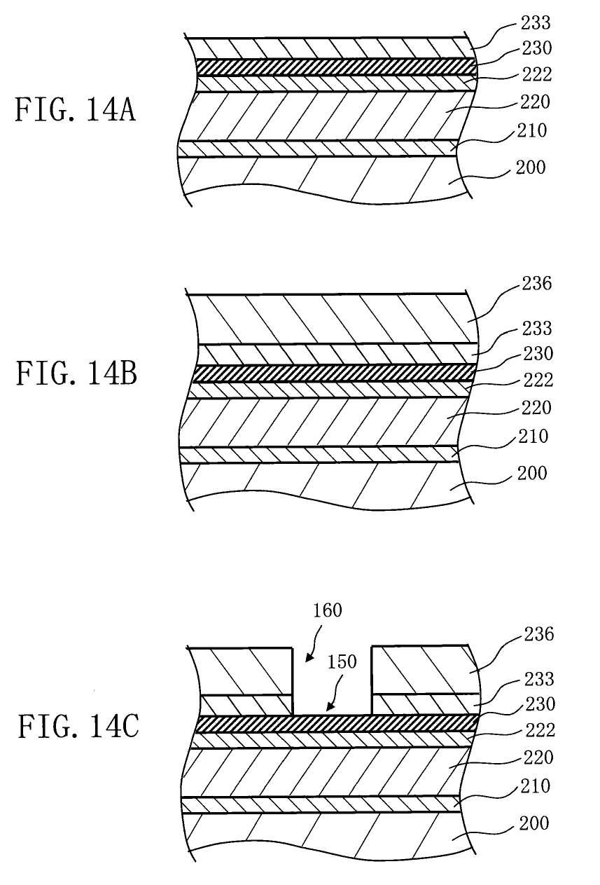

FIG. 14A to FIG. 14C are process sectional views showing processes performed corresponding to the flow chart in FIG. 13. FIG. 14A to FIG. 14C show the Si containing organic antireflection film formation process (S113) to the antireflection film etching process (S120) in FIG. 13.

In FIG. 14A, as the Si containing organic antireflection film formation process (S113), an organic antireflection film 233 containing silicon is formed on the metal containing film 230 in the state of FIG. 2D to a thickness of, for example, 30 nm. That is, an organic film containing carbon and silicon is used as the antireflection film 233. While the antireflection film 234 in the embodiment 1 is removed together with the resist film 236 in the ashing process (S124), the antireflection film 233 in the embodiment 3 has concentrations of silicon (Si) high enough so that the antireflection film 233 is not removed by ashing. For example, the antireflection film 233 is not removed by ashing can be created by setting the Si content to 30 wt % or more. By creating an organic film whose Si content is 30 wt % or more, the antireflection film 233 whose resistance to etching is stronger than that of an organic film containing no Si and which is etched together when the cap film 222 or the low-k film 220 is etched, resulting from the fact that Si or C to be a component element of the low-k film 220 is contained, can be created.

In FIG. 14B, as the resist coating process (S114), the antireflection film 233 is coated with a resist material to form the resist film 236. The resist coating process (S114) is the same as in the embodiment 1 except that the resist film 236 is formed on the Si containing organic antireflection film 233. Then, as the resist pattern formation process (S116), a resist pattern is formed on the antireflection film 233 by undergoing a lithography process such as an exposure process to selectively form the opening 160.

In FIG. 14C, as the antireflection film etching process (S120), the opening 150 is formed by selectively etching the exposed antireflection film 233 by the anisotropic etching method using the resist pattern as a mask. Here, the metal containing film 230 can be used as an etching stopper. By using the anisotropic etching method for removal, the opening 150 can be formed substantially perpendicularly to the surface of the substrate 200. As an example, for example, the opening 150 may be formed by the reactive ion etching method.

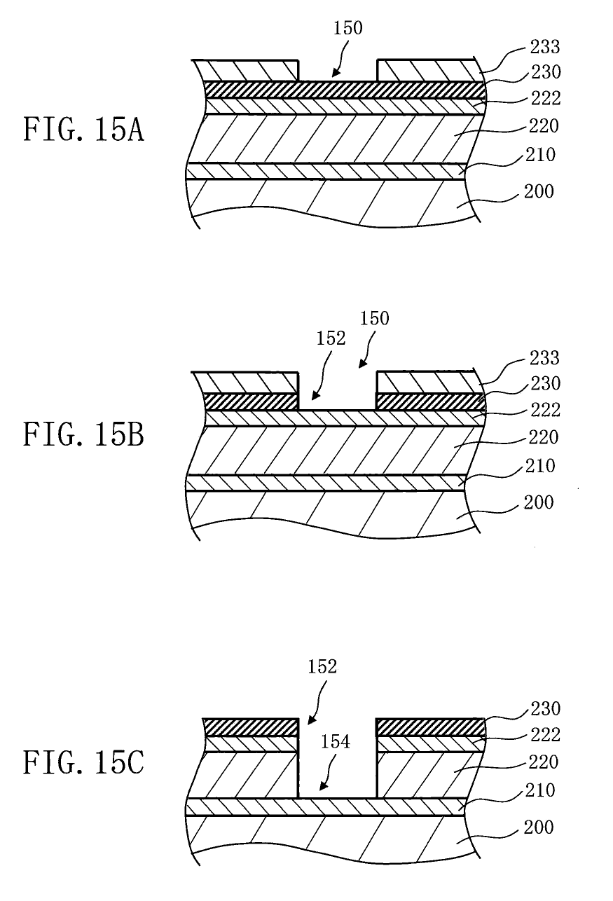

FIG. 15A to FIG. 15C are process sectional views showing processes performed corresponding to the flow chart in FIG. 13. FIG. 15A to FIG. 15C show the ashing process (S124) to part of the dielectric film and etching stopper film etching process (S129) in FIG. 13.

In FIG. 15A, as the ashing process (S124), the resist film 236 remaining on the antireflection film 233 is removed by ashing. That is, the resist film 236 constituting a resists pattern is removed by ashing in a state in which the antireflection film 233 is left after the antireflection film 233 being selectively etched and before the low-k film 220 being etched. By removing the resist pattern in a state in which the antireflection film 233 is left before the low-k film 220 being etched, a surface different from the opening 150 of the antireflection film 233, that is, an upper surface here is exposed. By exposing the upper surface of the antireflection film 233 in this manner, C containing reaction products can be caused to be generated when the low-k film 220 is etched. The ashing process (S124) here is an example of the resist pattern removal process. Since the antireflection film 233 has Si content of 30 wt % or more, the antireflection film 233 can remain without being removed by ashing. By removing the resist pattern on the antireflection film 233 when the low-k film 220 is etched, instead of leaving the resist pattern by the resist film 236 until the low-k film 220 is etched, the total thickness of the film to be a mask material becomes thinner so that dimensional accuracy when the low-k film 220 is etched can be improved.

In FIG. 15B, as the metal containing film etching process (S126), the opening 152 is formed by selectively etching the exposed metal containing film 230 by the anisotropic etching method using the antireflection film 233 as a hard mask.

In FIG. 15C, as the dielectric film and etching stopper film etching process (S129), the opening 154 is formed by selectively etching the exposed cap film 222 and the low-k film 220 thereunder by the anisotropic etching method using the antireflection film 233 and the metal containing film 230 as hard masks in a state in which a surface of the antireflection film 233 different from the opening 150 is exposed. When the low-k film 220 is etched, C containing reaction products are generated from the antireflection film 233 and C can be inhibited from escaping from the inner wall of the opening of the low-k film 220 by the C containing reaction products being stuck to the inner wall of the opening of the cap film 222 and the low-k film 220.

Here, when the low-k film 220 is etched, the film is reduced by the antireflection film 233 also being etched together. Then, when etching of the low-k film 220 is finished, the antireflection film 233 can be made to disappear. The antireflection film 233 disappears before or when etching of the low-k film 220 is finished and the C containing reaction products need not be supplied until etching of the low-k film 220 is finished and generation of C containing reaction products of a certain thickness is sufficient. Under predetermined conditions, though dependent on etching conditions, for example, 1 to 10 nm or so of C containing reaction products is sufficient to produce an effect.

Since the antireflection film 233 disappears by the time when etching of the low-k film 220 is finished, the etching stopper film 210 below the opening 154 only needs to be removed by etching in the dielectric film and etching stopper film etching process (S129) and the need to independently provide a process to remove the antireflection film 233 can be eliminated. As a result, working damage of the low-k film 220 by plasma exposed when the antireflection film 233 is removed can be avoided. Processes after the barrier metal film formation process (S132) is the same as in the embodiment 1.

By using an antireflection film serving also as a C containing film, as described above, formation of an independent C containing film can be omitted.

### Embodiment 4

In the embodiment 2, the antireflection film 234 is formed after the C containing film 232 being formed. In the embodiment 4, a configuration in which an antireflection film serving also as a C containing film is used without using the independent C containing film 232 will be described. The embodiment 4 will be described below with reference to drawings.

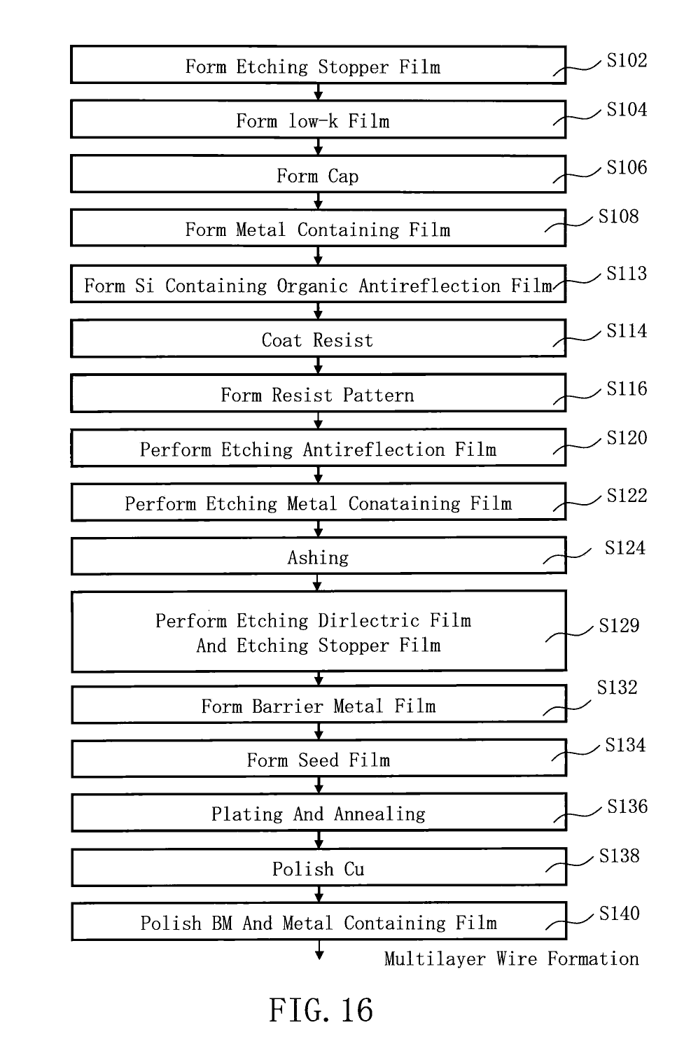

FIG. 16 is a flow chart showing features of the method for fabricating a semiconductor device according to the embodiment 4. FIG. 16 is the same as FIG. 13 except that a metal containing film etching process (S122) is added between the antireflection film etching process (S120) and the ashing process (S124) and the metal containing film etching process (S126) is removed. Thus, the etching stopper film formation process (S102) to the antireflection film etching process (S120) are the same as in the embodiment 3.

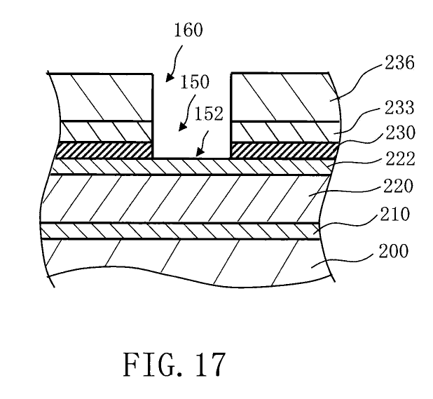

FIG. 17 is a process sectional view showing a process performed in the metal containing film etching process (S122) in FIG. 16. In FIG. 17, as the metal containing film etching process (S122), the opening 152 is formed by selectively etching the exposed metal containing film 230 by the anisotropic etching method using a resist pattern by the resist film 236 as a mask in the state shown in FIG. 14C. For example, etching is performed in a different reaction vessel from that in the antireflection film etching process (S120) or the ashing process (S124). Here, the cap film 222 can be used as an etching stopper.

Then, the state of FIG. 15B is created after performing the ashing process (S124). Subsequent processes are the same as in the embodiment 3.

In the embodiment 4, the antireflection film 233 can be prevented from producing a facet when the metal containing film 230 is etched by using a resist pattern formed on the antireflection film 233 as a mask, instead of using the antireflection film 233 as a hard mask while the organic antireflection film 233 containing Si is exposed. As a result, a hard mask pattern of the antireflection film 233 can be maintained in a satisfactory state until the low-k film 220 is etched. Also as a result, the opening 154 for embedding a Cu wire can be formed with more precise dimensions than those in the embodiment 3. Further, by removing the resist pattern on the antireflection film 233 when the low-k film 220 is etched, instead of leaving the resist pattern by the resist film 236 until the low-k film 220 is etched, the total thickness of the film to be a mask material becomes thinner so that dimensional accuracy when the low-k film 220 is etched can be improved.

According to the present embodiment, working damage of a dielectric film can be inhibited by a carbon containing film when the dielectric film is etched. As a result, a semiconductor device having sufficient electric characteristics can be fabricated.

In the above description, the same effect can be obtained, in addition to Cu, as a material of the wire layer in each of the above embodiments, a material having Cu as a main component used in the semiconductor industry such as a Cu—Sn alloy, Cu—Ti alloy, and Cu—Al alloy.

In the foregoing, embodiments have been described with reference to concrete examples. However, the present invention is not limited to these concrete examples.

Further, the thickness of inter-level dielectric, the size, shape, and number of openings and the like may be used by selecting what is needed for semiconductor integrated circuits and various semiconductor elements as needed.

In addition, all semiconductor devices and methods for fabricating semiconductor devices having elements of the invention and whose design can be modified as needed by those skilled in the art are included in the scope of the present invention.

Though techniques normally used in the semiconductor industry, for example, a lithography process and cleaning before and after treatment are omitted for simplification of the description, such techniques are naturally included in the scope of the invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method for fabricating a semiconductor device, comprising:
forming a dielectric film above a substrate;
forming a metal containing film above the dielectric film;
forming at least one carbon containing film of a silicon carbon containing film containing silicon and carbon and a nitrogen carbon containing film containing nitrogen and carbon above the metal containing film;
etching the carbon containing film selectively;
etching the metal containing film selectively to transfer an opening of the carbon containing film formed by etching; and
etching the dielectric film using the carbon containing film and the metal containing film as masks in a state in which a surface of the carbon containing film other than the opening is exposed.

2. The method according to claim 1, further comprising:
forming a barrier metal film on the metal containing film and on an inner surface of an opening transferred and formed in the dielectric film using a material identical to that of the metal containing film in a state in which only the metal containing film of the metal containing film and the carbon containing film used as masks for etching the dielectric film is left;
depositing a conductive material on the barrier metal film;
leaving the conductive material selectively in the opening on whose inner surface the barrier metal film is formed by polishing the conductive material; and
polishing the barrier metal film on the metal containing film and the metal containing film after selectively leaving the conductive material in the opening.

3. The method according to claim 2, wherein the dielectric film has a low dielectric constant film whose relative dielectric constant is less than 2.5 and a cap film formed on the low dielectric constant film.

4. The method according to claim 1, further comprising: forming a resist pattern above the carbon containing film, wherein
the carbon containing film is etched using the resist pattern as a mask, and
the metal containing film is etched using the carbon containing film as a mask.

5. The method according to claim 4, wherein the surface of the carbon containing film other than the opening is exposed by removing the resist pattern in a state in which the carbon containing film is left before the metal containing film being etched.

6. The method according to claim 1, further comprising: forming a resist pattern above the carbon containing film, wherein
the carbon containing film and the metal containing film are etched using the resist pattern as a mask.

7. The method according to claim 6, wherein the surface of the carbon containing film other than the opening is exposed by removing the resist pattern in a state in which the carbon containing film is left before the dielectric film being etched.

8. The method according to claim 1, wherein the carbon containing film is an organic film containing carbon and silicon, and
when the dielectric film is etched, the carbon containing film is also removed together.

9. The method according to claim 1, wherein the metal containing film contains at least one of tantalum (Ta), titanium (Ti), ruthenium (Ru), tungsten (W), zirconium (Zr), aluminum (Al), and niobium (Nb) as a material.

10. The method according to claim 1, wherein the carbon containing film serves also as an antireflection film.

11. The method according to claim 10, further comprising: forming a resist pattern on the carbon containing film serving also as the antireflection film, wherein
at least the carbon containing film is etched using the resist pattern as a mask and after the carbon containing film being etched, the resist pattern is removed by ashing in a state in which the carbon containing film is left.

12. The method according to claim 11, wherein the carbon containing film is an organic film containing silicon and carbon and silicon content is 30 wt % or more.

13. The method according to claim 12, wherein when the dielectric film is etched, the carbon containing film disappears before etching of the dielectric film is finished.

14. The method according to claim 1, further comprising: forming an antireflection film on the carbon containing film; and
forming a resist pattern on the antireflection film, wherein
at least the antireflection film and the carbon containing film are selectively etched using the resist pattern as a mask.

15. The method according to claim 14, wherein the antireflection film is removed together with the resist pattern after the antireflection film and the carbon containing film being selectively etched.

16. The method according to claim 1, wherein a material whose resistance to etching is stronger than that of the dielectric film is used as a material of the carbon containing film.

17. The method according to claim 1, wherein at least one of silicon carbide (SiC), silicon carbonitride (SiCN), and carbon nitride (CN) is used as a material of the carbon containing film.

18. The method according to claim 1, wherein an etching stopper film is formed between the dielectric film and the substrate,
the dielectric film is etched using the etching stopper film as a stopper, and
after the dielectric film being etched, the etching stopper film is removed together with the carbon containing film.

19. The method according to claim 18, wherein at least one of SiCN, SiC, and SiN is used as a material of the etching stopper film.

20. A method for fabricating a semiconductor device, comprising:
forming a dielectric film above a substrate;
forming a metal containing film above the dielectric film;
forming a carbon containing film whose resistance to etching is stronger than that of the dielectric film above the metal containing film;
etching the carbon containing film selectively;
etching the metal containing film selectively to transfer an opening of the carbon containing film formed by etching; and
etching the dielectric film using the carbon containing film and the metal containing film as masks in a state in which a surface of the carbon containing film other than the opening is exposed.
